(19) United States
(12) Patent Application Publication
(10) Pub. No.: US 2025/0048811 A1
(43) Pub. Date: Feb. 6, 2025

(54) DISPLAY SUBSTRATE AND METHOD FOR PREPARING THE SAME, DISPLAY DEVICE

(71) Applicants: BOE MLED TECHNOLOGY CO., LTD., Beijing (CN); BOE TECHNOLOGY GROUP CO., LTD., Beijing (CN)

(72) Inventors: Jiao LI, Beijing (CN); Chenchang CHEN, Beijing (CN); Ruoyu MA, Beijing (CN); Liangliang JIN, Beijing (CN); Zezhou YANG, Beijing (CN); Wenjia SUN, Beijing (CN); Qingkai ZHANG, Beijing (CN); Le ZHAO, Beijing (CN); Weixing LIU, Beijing (CN)

(21) Appl. No.: 18/705,333

(22) PCT Filed: Jan. 18, 2023
(86) PCT No.: PCT/CN2023/072817

§ 371 Date: Apr. 26, 2024

(51) Int. Cl. H01L 33/60; H01L 25/16

(52) U.S. Cl. CPC H01L 33/60; H01L 25/167

(57) ABSTRACT

The present disclosure provides a display substrate, a preparing method thereof, and a display device. The display substrate includes: a base substrate including a spacing region; a plurality of light-emitting device groups on the base substrate, any two adjacent light-emitting device groups of the plurality of light-emitting device groups being spaced apart from each other by the spacing region; and a light-shielding layer on the base substrate. The light-shielding layer covers the plurality of light-emitting device groups and fills the spacing region, a first portion of the light-shielding layer covering the plurality of light-emitting device groups has a first thickness, a second portion of the light-shielding layer filling the spacing region has a second thickness, the first thickness is less than the second thickness.

### TECHNICAL FIELD

The present disclosure relates to the field of display technology, and in particular, to a display substrate, a method for preparing the same, and a display device comprising the display substrate.

### BACKGROUND

Mini light-emitting diode (Mini LED) and Micro light-emitting diode (Micro LED) are a new type of LED display technology derived from small-pitch LEDs. Generally, the size of Mini LED is about 100˜300 μm, and the size of Micro LED is below 100 μm. Because Mini LED and Micro LED have advantages such as superior display effect, thin and light size, high contrast, and long lifetime, they are increasingly used in the display field.

### SUMMARY

According to an aspect of the present disclosure, a display substrate is provided. The display substrate comprises: a base substrate comprising a spacing region; a plurality of light-emitting device groups on the base substrate, any two adjacent light-emitting device groups of the plurality of light-emitting device groups being spaced apart from each other by the spacing region; and a light-shielding layer on the base substrate. The light-shielding layer covers the plurality of light-emitting device groups and fills the spacing region, a first portion of the light-shielding layer covering the plurality of light-emitting device groups has a first thickness, a second portion of the light-shielding layer filling the spacing region has a second thickness, and the first thickness is less than the second thickness.

In some embodiments, the first portion of the light-shielding layer is spaced apart from the plurality of light-emitting device groups in a thickness direction of the base substrate.

In some embodiments, the display substrate further comprises a reflective dam, the reflective dam is arranged on the base substrate along a first direction and a second direction intersecting with the first direction, and the reflective dam at least surrounds each of the plurality of light-emitting device groups.

In some embodiments, each light-emitting device group comprises a plurality of light-emitting devices, and a thickness of the reflective dam is greater than a thickness of a light-emitting device in a thickness direction of the base substrate.

In some embodiments, the reflective dam surrounding each light-emitting device group forms a reflective cup.

In some embodiments, the display substrate further comprises a diffusion structure, the diffusion structure covers each light-emitting device group, and an orthographic projection of each light-emitting device group on the base substrate falls within an orthographic projection of the diffusion structure on the base substrate.

In some embodiments, in a thickness direction of the base substrate, the first portion of the light-shielding layer is spaced apart from the plurality of light-emitting device groups by the diffusion structure.

In some embodiments, each light-emitting device group comprises a plurality of light-emitting devices, and the diffusion structure is at least on a side of the plurality of light-emitting devices away from the base substrate and in a region between any two adjacent light-emitting devices of the plurality of light-emitting devices.

In some embodiments, a part of the diffusion structure on the side of the plurality of light-emitting devices away from the base substrate is a first part of the diffusion structure, a cross section of the first part of the diffusion structure comprises a plurality of protrusion units, any one of the plurality of protrusion units corresponds to one of the plurality of light-emitting device groups, the cross section of the first part of the diffusion structure is a section of the first part of the diffusion structure in a direction parallel to the base substrate. Each light-emitting device group comprises three light-emitting devices, each protrusion unit comprises three protrusions, and orthographic projections of the three protrusions on the base substrate at least partially overlap with orthographic projections of the three light-emitting devices of a corresponding light-emitting device group on the base substrate.

In some embodiments, a thickness of the diffusion structure is greater than a thickness of a light-emitting device in the thickness direction of the base substrate.

In some embodiments, the diffusion structure is further on a surface of the reflective dam away from the base substrate.

In some embodiments, the diffusion structure comprises a diffusion glue and diffusion particles distributed in the diffusion glue.

In some embodiments, an orthographic projection of the first portion of the light-shielding layer on the base substrate at least partially overlaps with the orthographic projection of the diffusion structure on the base substrate, and an orthographic projection of the second portion of the light-shielding layer on the base substrate does not overlap with the orthographic projection of the diffusion structure on the base substrate.

In some embodiments, in a thickness direction of the base substrate, a thickness of the diffusion structure is substantially equal to a thickness of the reflective dam.

In some embodiments, a distance from at least one point on a surface of the diffusion structure away from the base substrate to the base substrate is greater than a distance from a surface of the reflective dam away from the base substrate to the base substrate.

In some embodiments, the surface of the diffusion structure away from the base substrate is a convex surface.

In some embodiments, a shape of the diffusion structure is hemispherical.

In some embodiments, the display substrate further comprises a plurality of driving circuits. Any one of the plurality of driving circuits is electrically connected to one of the plurality of light-emitting device groups, and the reflective dam and the diffusion structure together wrap each light-emitting device group and each driving circuit.

In some embodiments, the display substrate further comprises a base layer on a side of the light-shielding layer away from the base substrate, the light-shielding layer is attached to a surface of the base layer facing the base substrate.

In some embodiments, the display substrate is a low-temperature polysilicon display substrate.

In some embodiments, the light-shielding layer comprises a flame retardant.

According to another aspect of the present disclosure, a display device comprising the display substrate described in any of the previous embodiments is provided.

According to yet another aspect of the present disclosure, a method of preparing a display substrate is provided. The method comprises: providing a base substrate, the base substrate comprising a spacing region; forming a plurality of light-emitting device groups on the base substrate, any two adjacent light-emitting device groups of the plurality of light-emitting device groups being spaced apart from each other by the spacing region; and assembling a base layer coated with a light-shielding layer with the base substrate on which the plurality of light-emitting device groups are formed to enable the light-shielding layer to cover the plurality of light-emitting device groups and to fill the spacing region, a first portion of the light-shielding layer covering the plurality of light-emitting device groups having a first thickness, a second portion of the light-shielding layer filling the spacing region having a second thickness, and the first thickness being less than the second thickness.

In some embodiments, before the assembling a base layer coated with a light-shielding layer with the base substrate on which the plurality of light-emitting device groups are formed, the method further comprises: forming a reflective dam on the base substrate, the reflective dam being arranged along a first direction and a second direction intersecting with the first direction, and the reflective dam at least surrounding each of the plurality of light-emitting device groups; and filling a diffusion structure in a region defined by the reflective dam to enable the diffusion structure to cover each light-emitting device group, an orthographic projection of each light-emitting device group on the base substrate falling within an orthographic projection of the diffusion structure on the base substrate.

In some embodiments, the assembling a base layer coated with a light-shielding layer with the base substrate on which the plurality of light-emitting device groups are formed, comprises: aligning the base layer coated with a light-shielding glue having a uniform thickness with the base substrate on which the plurality of light-emitting device groups, the reflective dam and the diffusion structure are formed, a portion of the light-shielding glue being extruded from a position aligned with the light-emitting device groups to a position aligned with the spacing region through vacuum lamination and extrusion, to form the light-shielding layer comprising the first portion having the first thickness and the second portion having the second thickness, the light-shielding layer being attached to the base substrate.

In some embodiments, in a thickness direction of the base substrate, a thickness of the light-shielding glue is less than a thickness of the reflective dam.

In some embodiments, the forming a reflective dam on the base substrate, comprises: forming the reflective dam on the base substrate through a method of multiple printings in a stacked manner. A longitudinal section of the reflective dam is a trapezoid, and the longitudinal section of the reflective dam is a section of the reflective dam in a thickness direction of the base substrate.

In some embodiments, forming the plurality of light-emitting device groups on the base substrate is before forming the reflective dam on the base substrate.

### BRIEF DESCRIPTION OF THE DRAWINGS

In order to describe the technical solutions in the embodiments of the present disclosure more clearly, the drawings needed to be used in the embodiments will be briefly introduced below. Obviously, the drawings in the following description are only some embodiments of the present disclosure. Those of ordinary skill in the art can also obtain other drawings based on these drawings without undue experimentation.

FIG. 1 illustrates a plan view of a display substrate according to an embodiment of the present disclosure;

FIG. 2 illustrates a schematic cross sectional view of a partial structure taken along line AA′ of FIG. 1;

FIG. 3 illustrates graphs of the variation of light brightness with the viewing angle of a comparison display substrate and a display substrate according to an embodiment of the present disclosure;

FIG. 4 illustrates a morphology diagram of a display substrate under a microscope before forming the light-shielding layer according to an embodiment of the present disclosure;

FIG. 5A illustrates a morphology graph of a cross section of the display substrate of FIG. 4;

FIG. 5B illustrates a morphology graph of a longitudinal section of the display substrate of FIG. 4;

FIG. 6 illustrates a schematic cross sectional view of a partial structure of a display substrate according to an embodiment of the present disclosure;

FIG. 7 illustrates a block diagram of a display device according to an embodiment of the present disclosure;

FIG. 8 illustrates a flow chart of a method of preparing a display substrate according to an embodiment of the present disclosure; and

FIG. 9 illustrates a schematic structural diagram of a display substrate in different steps of a method according to an embodiment of the present disclosure.

### DETAILED DESCRIPTION OF THE DISCLOSURE

The technical solutions in the embodiments of the present disclosure will be clearly described below with reference to the accompanying drawings. Obviously, the described embodiments are only some, but not all, of the embodiments of the present disclosure. Based on the embodiments of the present disclosure, all other embodiments obtained by those of ordinary skill in the art without undue experimentation fall within the scope of protection of this disclosure.

Mini LED and Micro LED displays have attracted more and more attention in the display field due to their advantages such as ultra-narrow seams, high brightness, high color gamut, high dynamic contrast, and long lifetime. However, the intensity distribution of the light emitted by Mini LEDs or Micro LEDs of different colors on the display substrate is usually different at different viewing angles, and the display substrate is also reflective due to the presence of some layers, therefore, the display substrate based on Mini LED or Micro LED has problems such as a large viewing angle color cast (that is, there is a difference in the color of the picture between a large viewing angle and a side viewing angle) and a high L value in the black state. Here, “viewing angle” refers to the angle between the line of sight and the vertical direction of the display. The L value is used to characterize the brightness of an object. For a display product, when the display substrate is not lit but is in a black state, the smaller the L value, the better.

In order to reduce the L value in the black state, a light-shielding layer may be introduced into the display substrate. However, improper setting of the light-shielding layer will significantly block the light emitted by the Mini LED or Micro LED light-emitting devices and reduce the transmittance of the emitted light. In order to achieve the expected light-emitting brightness, the power consumption of the light-emitting device needs to be greatly increased, resulting in a significant increase in the power consumption of the display substrate.

Therefore, there is an urgent need to propose a solution that can not only overcome at least one of the large viewing angle color cast and high L value in the black state as mentioned above, but also do not affect the transmittance of the emitted light of the light-emitting device.

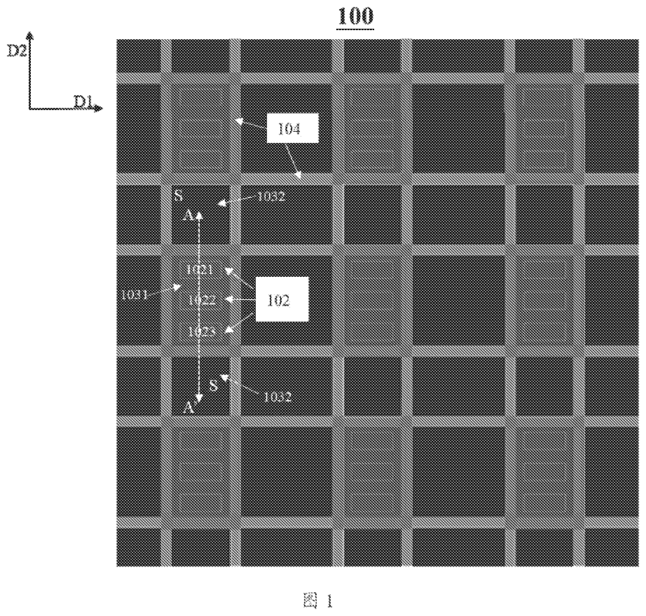

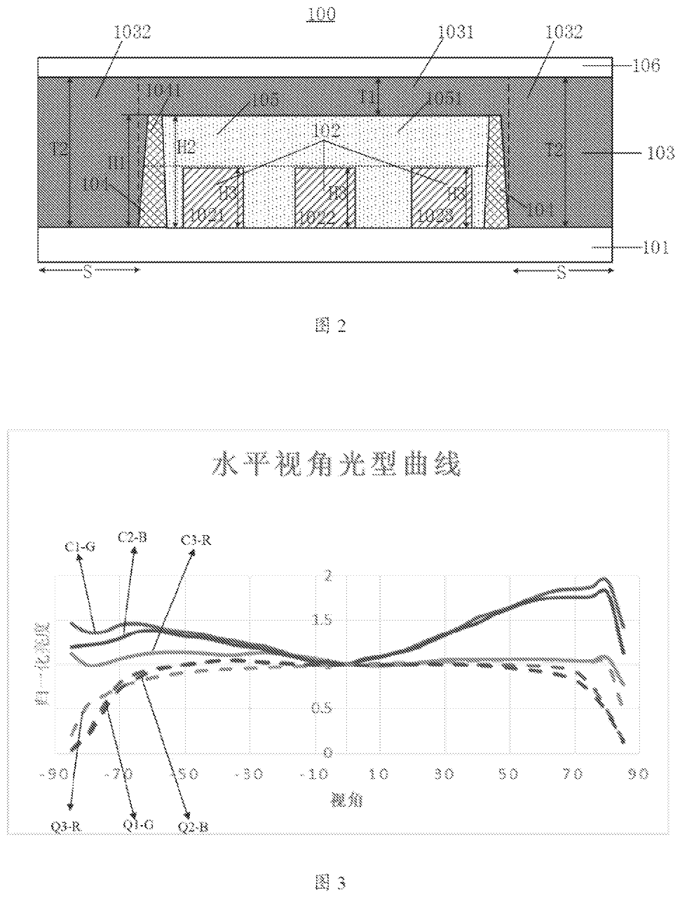

In view of this, embodiments of the present disclosure provide a display substrate. FIG. 1 illustrates a plan view of a display substrate 100, and FIG. 2 illustrates a schematic cross sectional view taken along line AA′ of FIG. 1. As illustrated in FIGS. 1 and 2, the display substrate 100 comprises: a base substrate 101 on which a plurality of spacing regions S are arranged; a plurality of light-emitting device groups 102 on the base substrate 101, any two adjacent light-emitting device groups 102 of the plurality of light-emitting device groups 102 being spaced apart from each other by the spacing region S; and a light-shielding layer 103 located on the base substrate 101. The light-shielding layer 103 covers the plurality of light-emitting device groups 102 and fills the plurality of spacing regions S, a first portion 1031 of the light-shielding layer 103 covering the plurality of light-emitting device groups 102 has a first thickness T1, a second portion 1032 of the light-shielding layer 103 filling the spacing region S has a second thickness T2, the first thickness T1 is less than the second thickness T2.

As conveyed by the literal, the light-shielding layer 103 has a shielding effect on light. The sources of light comprise but are not limited to the reflected light from the display substrate 100 to the outside and the emitted light from the light-emitting device groups 102. The display substrate 100 needs to have good black color when displaying a black picture. The display substrate 100 is usually provided with some metal traces. For example, some of the metal traces are located in the spacing region S of the display substrate 100, these metal traces have the reflection effect on the external ambient light and the light emitted by the light-emitting device groups 102, thus interfering with the normal display of the display picture and making the color uniformity of the display picture poor. The light-shielding layer 103 can reduce the reflectivity of these metal traces to light, and can also shield the metal traces, uneven locations, and components that are not intended to be seen by the user on the display substrate 100, thereby making the display substrate 100 appear to have good uniformity. By making the second portion 1032 of the light-shielding layer 103 filling the spacing region S have a thicker second thickness T2, it can well blacken the display substrate 100, so that the display substrate 100 has a low black state L value. By making the first portion 1031 of the light-shielding layer 103 covering the plurality of light-emitting device groups 102 have a thinner first thickness T1, the light emitted by the light-emitting device groups 102 may not be substantially blocked, so that the light can pass through the first portion 1031 to be exited, thereby achieving high transmittance. It can be seen that by making the light-shielding layer 103 have an uneven thickness, that is, a thicker thickness T2 is provided at the position where the light-shielding layer 103 should provide a light-shielding effect so as to achieve good light-shielding, a thinner thickness T1 is provided at the position where light should be transmitted so as to achieve high transmittance, this solution can achieve high transmittance while ensuring that the display substrate 100 has a high blackness. The realization of high transmittance can prevent the light-emitting device group 102 from additionally increasing the brightness, thereby reducing the power consumption of the display substrate 100.

FIG. 1 illustrates only nine light-emitting device groups 102 as an example, and one of the light-emitting device groups 102 is labeled. However, it is known that the display substrate 100 may comprise a plurality of light-emitting device groups 102, and any two adjacent light-emitting device groups 102 among the plurality of light-emitting device groups 102 are spaced apart from each other by the spacing region S. Each light-emitting device group 102 may comprise multiple light-emitting devices. For example, each light-emitting device group 102 may comprise three light-emitting devices 1021, 1022 and 1023, the three light-emitting devices 1021, 1022 and 1023 may respectively emit light of different colors. For example, the light-emitting device 1021 may emit red light, the light-emitting device 1022 may emit green light, and the light-emitting device 1023 may emit blue light. In some embodiments, each light-emitting device may be Mini LED or Micro LED. Generally, the size of Mini LED is about 100˜300 μm, and the size of Micro LED is below 100 μm.

The material of the light-shielding layer 103 may be any material with light-shielding effect. In some embodiments, the light-shielding layer 103 is a black glue layer, and the material of the black glue layer may be black optically clear adhesive (OCA). During the preparation stage, the black glue layer has high fluidity. When the black glue layer is attached to the base substrate 101 formed with a diffusion structure 105, through vacuum lamination and extrusion, a part of the black glue layer is extruded from a position aligned with the light-emitting device group 102 to a position aligned with the spacing region S, thus the light-shielding layer 103 comprising the first portion 1031 having the first thickness T1 and the second portion 1032 having the second thickness T2 is formed. As illustrated in FIG. 1, since the light-emitting device group 102 is topped by the first portion 1031 of the light-shielding layer 103 with a thinner thickness, light can pass through the first portion 1031 and have a high transmittance, so that the first portion 1031 of the light-shielding layer 103 in FIG. 1 appears a lighter gray. The gaps of the display substrate 100 that are not filled with the diffusion structure 105, that is, the spacing regions S, are filled with the thicker second portion 1032 of the light-shielding layer 103. The thicker second portion 1032 can well blacken the display substrate 100, thus the second portion 1032 of the light-shielding layer 103 in FIG. 1 appears a deeper black.

In some embodiments, the first thickness Tl of the first portion 1031 of the light-shielding layer 103 is approximately 50 μm. In actual process, the specific thickness of the first portion 1031 of the light-shielding layer 103 may be determined based on factors such as the spacing between the light-emitting devices of the light-emitting device group 102, the size of the light-emitting device, the size of the reflective dam 104, and the thickness of the diffusion structure 105 (the reflective dam 104 and the diffusion structure 105 will be described later).

In some embodiments, a flame retardant may be added to the light-shielding layer 103.

As illustrated in FIGS. 1 and 2, in some embodiments, the display substrate 100 may further comprise a reflective dam 104. The reflective dam 104 is arranged on the base substrate 101 along a first direction D1 and a second direction D2 intersecting with the first direction D1. The first direction D1 may be, for example, the horizontal direction in FIG. 1, and the second direction D2 may be, for example, the vertical direction perpendicular to the horizontal direction in FIG. 1. The reflective dam 104 is arranged in a strip shape in the first direction D1 and is also arranged in a strip shape in the second direction D2. The reflective dam 104 at least surrounds each light-emitting device group 102. Part of the light emitted by the light-emitting devices 1021, 1022 and 1023 of the light-emitting device group 102 irradiates the reflective dam 104, since the reflective dam 104 is reflective and surrounds each light-emitting device group 102, the reflective dam 104 can reflect the light irradiated thereon. At least a part of the reflected light can pass through the surface of the light-shielding layer 103 and be emitted to the outside of the display substrate 100, thereby improving the utilization rate of light emitted by the light-emitting device groups 102. In some embodiments, the material of the reflective dam 104 is, for example, white oil or other materials with high reflectivity.

In some embodiments, the reflective dam 104 surrounding each light-emitting device group 102 forms a reflective cup, which may be a trapezoidal reflective cup, for example. The reflective dam 104 in the form of a reflective cup can collect the light emitted by the light-emitting devices 1021 to 1023 in the reflective cup to improve the brightness at the front viewing angle.

The distance between the reflective dam 104 and the light-emitting device may be appropriately adjusted as needed. In some embodiments, the distance between the reflective dam 104 and the light-emitting device is 30˜200 μm, and the value of the distance is related to the type and size of the light-emitting device. The distance between the reflective dam 104 and the light-emitting device determines the amount of diffusion glue that can be filled around the pixel, thereby affecting the adjustment of the light pattern of the light-emitting device. In an example, the distance between the reflective dam 104 and the light-emitting device is about 160 μm, in this case, the reflective dam 104 may be referred to as a large dam. In an alternative example, the distance between the reflective dam 104 and the light-emitting device is about 60 μm, in this case, the reflective dam 104 may be referred to as a small dam.

As illustrated in FIGS. 1 and 2, in some embodiments, the display substrate 100 may further comprise a diffusion structure 105. The reflective dam 104 surrounds each light-emitting device group 102 to define a filling region, and the diffusion structure 105 is filled in the filling region. The diffusion structure 105 covers each light-emitting device group 102, and the orthographic projection of each light-emitting device group 102 on the base substrate 101 falls within the orthographic projection of the diffusion structure 105 on the base substrate 101. The diffusion structure 105, the reflective dam 104 and the light-shielding layer 103 form an encapsulation structure to achieve encapsulation of the light-emitting device group 102. The diffusion structure 105 comprises diffusion glue and diffusion particles distributed in the diffusion glue. In some examples, the diffusion glue may be transparent OCA glue, and the diffusion particles may be nanoscale TiO₂ particles or SiO₂ particles or other nanometer-sized particles with diffusion effect. If the diffusion structure 105 is not used to encapsulate the light-emitting device group 102, that is, the light-emitting devices of the light-emitting device group are exposed, the light pattern emitted by the light-emitting device is usually not smooth and the color cast is serious. By introducing the diffusion structure 105, the diffusion particles in the diffusion structure 105 can adjust the light pattern emitted by the light-emitting device and improve the color cast phenomenon.

The diffusion structure 105 is at least located on a side of the plurality of light-emitting devices 1021˜1023 of each light-emitting device group 102 away from the base substrate 101 and in a region between any two adjacent light-emitting devices of the plurality of light-emitting devices 1021˜1023. In some examples, the diffusion structure 105 is located on the side of the plurality of light-emitting devices 1021˜1023 of each light-emitting device group 102 away from the base substrate 101, the region between any two adjacent light-emitting devices of the plurality of light-emitting devices 1021˜1023, and the gap between the reflective dam 104 and the light-emitting device. Filling the diffusion structure 105 between and above the light-emitting devices helps to further adjust the light pattern of the light emitted by the light-emitting devices and improve the color cast.

In some examples, the diffusion structure 105 may also be located on a surface of the reflective dam 104 away from the base substrate 101. Since the diffusion structure 105 is formed after the reflective dam 104 is formed in the preparation process, the diffusion structure 105 is likely to remain on the surface of the reflective dam 104 away from the base substrate 101.

In some embodiments, in the thickness direction of the base substrate 101, the thickness H1 of the reflective dam 104 is greater than the thickness H3 of the light-emitting device 1021, 1022 or 1023 of the light-emitting device group 102. In some examples, the thickness H1 of the reflective dam 104 is 5˜50 μm larger than the thickness H3 of the light-emitting device 1021, 1022 or 1023. The thickness H1 of the reflective dam 104 is related to the thickness H3 of the light-emitting device 1021, 1022 or 1023. If the light-emitting device 1021, 1022 or 1023 is Mini LED and its thickness H3 is 60˜100 μm, the thickness H1 of the reflective dam 104 is approximately 20˜50 μm greater than the thickness H3 of the light-emitting device 1021, 1022 or 1023. If the light-emitting device 1021, 1022 or 1023 is Micro LED and its thickness H3 is 5˜10 μm, the thickness H1 of the reflective dam 104 is approximately 5˜10 μm greater than the thickness H3 of the light-emitting device 1021, 1022 or 1023. As mentioned before, the reflective dam 104 surrounds each light-emitting device group 102 to define the filling region, and the diffusion structure 105 is filled in the filling region. Since the thickness H1 of the reflective dam 104 is greater than the thickness H3 of the light-emitting device 1021, 1022 or 1023, more diffusion structures 105 with the diffusion particles can be filled in the filling region defined by the reflective dam 104. The diffusion effect of the diffusion structure 105 on light is proportional to the concentration of the diffusion particles. Therefore, the more diffusion particles, the better the diffusion effect of the diffusion structure 105 on light, so that the light pattern emitted by the light-emitting device can be more fully adjusted. In order to further adjust the light pattern emitted by the light-emitting device so that the light intensity at various viewing angles is approximately the same, the filling region defined by the reflective dam 104 can be filled with the diffusion glue having specific concentration and specific amount of glue. The specific values of concentration and glue amount may be set according to the requirements of light intensity.

In the thickness direction of the base substrate 101, the first portion 1031 of the light-shielding layer 103 is spaced apart from the plurality of light-emitting device groups 102 through the diffusion structure 105, so that direct contact between the light-shielding layer 103 and the light-emitting device group 102 can be avoided. If the diffusion structure 105 is not disposed between the first portion 1031 of the light-shielding layer 103 and the light-emitting device group 102, the first portion 1031 of the light-shielding layer 103 will not only be in direct contact with the light-emitting device group 102, but also cause the first thickness T1 of the first portion 1031 of the light-shielding layer 103 to become thicker, which greatly affects the transmittance of the emitted light from the light-emitting device, causing increase of the power consumption of the display substrate. In the embodiments of the present disclosure, the diffusion structure 105 is disposed between the first portion 1031 of the light-shielding layer 103 and the light-emitting device group 102, in this way, not only the first portion 1031 of the light-shielding layer 103 is spaced apart from the light-emitting device group 102, but also the first thickness T1 is kept thin, thereby increasing the transmittance of emitted light from the light-emitting device and reducing the power consumption of the display substrate 100.

As illustrated in FIGS. 1 and 2, the orthographic projection of the first portion 1031 of the light-shielding layer 103 on the base substrate 101 at least partially overlaps with the orthographic projection of the diffusion structure 105 on the base substrate 101, and the orthographic projection of the second portion 1032 of the light-shielding layer 103 on the base substrate 101 does not overlap with the orthographic projection of the diffusion structure 105 on the base substrate 101. In other words, the thickness of the light-shielding layer 103 is thinner where the diffusion structure 105 is provided, and the thickness of the light-shielding layer 103 is thicker in the gap where the diffusion structure 105 is not provided, which ensures high transmittance while ensuring high blackness.

As illustrated in FIG. 2, in some embodiments, the thickness H1 of the reflective dam 104 is substantially equal to the thickness H2 of the diffusion structure 105 in the thickness direction of the base substrate 101, which ensures that the diffusion glue of the diffusion structure 105 will not overflow outside the reflective dam 104. “Substantially equal” here covers manufacturing errors due to process conditions.

In some embodiments, the thickness H2 of the diffusion structure 105 is greater than the thickness H3 of the light-emitting devices 1021˜1023 in the thickness direction of the base substrate 101, which ensures that there is enough diffusion glue above the light-emitting devices 1021˜1023 to adjust the light pattern of the emitted light. For example, the thickness H2 of the diffusion structure 105 is 20˜60 μm larger than the thickness H3 of the light-emitting devices 1021˜1023. The thickness H2 of the diffusion structure 105 may be flexibly adjusted according to the light pattern of the light-emitting device. For example, if the light pattern of the light-emitting device is smooth, less diffusion glue may be used to make the thickness H2 of the diffusion structure 105 thinner; if the light pattern of the light-emitting device fluctuates greatly, more diffusion glue may be used to make the thickness H2 of the diffusion structure 105 thicker.

In some embodiments, both sides of the diffusion structure 105 have recesses where they contact with the reflective dam 104. This is because during the preparation process of the display substrate 100, the reflective dam 104 is first printed on the base substrate 101, the reflective dam 104 is cured after printing, and then the diffusion glue is printed to form the diffusion structure 105. Since the diffusion glue is in a liquid state, the interface between the solid reflective dam 104 and the liquid diffusion glue forms a contact angle. Therefore, recesses will occur at the locations where both sides of the diffusion structure 105 are in contact with the reflective dam 104.

In some embodiments, the display substrate 100 may further comprise a base layer 106 located on a side of the light-shielding layer 103 away from the base substrate 101, and the light-shielding layer 103 is attached to a surface of the base layer 106 facing the base substrate 101. The material of the base layer 106 may be any suitable material. For example, the base layer 106 may be a polyethylene terephthalate (PET) film or a super retardation film (SRF).

The display substrate 100 may be a display substrate comprising a printed circuit board, a low-temperature polysilicon display substrate, a display substrate comprising a driving circuit, or the like. When the display substrate 100 is a display substrate comprising the driving circuit, the display substrate 100 comprises a plurality of driving circuits, and each driving circuit is electrically connected to a corresponding light-emitting device group 102 to control the multiple light-emitting devices of the light-emitting device group 102 to emit light. The reflective dam 104 and the diffusion structure 105 together wrap the plurality of light-emitting devices of each light-emitting device group 102 and each driving circuit. In some embodiments, the driving circuit may be an integrated circuit, especially a packaged chip with multiple terminals.

FIG. 3 illustrates graphs of the variation of light brightness with the viewing angle of a comparison display substrate and the display substrate 100 according to an embodiment of the present disclosure. Compared with the display substrate 100, the comparative display substrate has the same structures as the display substrate 100 except that it does not comprise the light-shielding layer 103, the reflective dam 104, and the diffusion structure 105. Therefore, the light-emitting device of the comparative display substrate is exposed and not encapsulated by the encapsulation structure, while the light-emitting device of the display substrate 100 is encapsulated by the encapsulation structure. In FIG. 3, the curve C1-G represents a curve showing the change of the brightness of the green light emitted by the light-emitting device of the comparison display substrate with the viewing angle, the curve C2-B represents a curve showing the change of the brightness of the blue light emitted by the light-emitting device of the comparison display substrate with the viewing angle, the curve C3-R represents a curve showing the change of the brightness of the red light emitted by the light-emitting device of the comparison display substrate with the viewing angle, the curve Q1-G represents a curve showing the change of the brightness of the green light emitted by the light-emitting device of the display substrate 100 with the viewing angle, the curve Q2-B represents a curve showing the change of the brightness of the blue light emitted by the light-emitting device of the display substrate 100 with the viewing angle, and the curve Q3-R represents a curve showing the change of the brightness of the red light emitted by the light-emitting device of the display substrate 100 with the viewing angle.

FIG. 3 illustrates the curves of the light pattern of the display substrate at a horizontal viewing angle. The abscissa represents the horizontal viewing angle, and the ordinate represents the normalized brightness. The horizontal viewing angle is based on the vertical normal line of the display substrate (that is, the vertical imaginary line in the middle of the display substrate), the viewing angle of a line of sight that is parallel to the normal line is a front viewing angle, which means that the user is viewing directly in front of the display substrate, the coordinate 0 in FIG. 3 represents the front viewing angle. The viewing angle of a line of sight that is not parallel to the normal line is a side viewing angle, which means that the user views the display substrate along the side viewing direction. The coordinate value in the positive direction of the horizontal axis in FIG. 3 is a positive number, and the coordinate value may represent, for example, the angle of the right viewing angle of the display substrate. The coordinate value in the negative direction of the horizontal axis in FIG. 3 is a negative number, and the coordinate value may represent, for example, the angle of the left viewing angle of the display substrate.

As can be seen from FIG. 3, for the three curves C1-G, C2-B and C3-R of the comparison display substrate, along the direction from the front viewing angle to the right viewing angle, as the angle increases (for example, from 0 degrees to 70 degrees), the brightness also increases, along the direction from the front viewing angle to the left viewing angle, as the angle increases (for example, from 0 degrees to −70 degrees), the brightness also increases, which is inconsistent with the viewing habits of human eyes for display products. Moreover, the degree of overlap of the three curves C1-G, C2-B and C3-R is low, which indicates that the light patterns emitted by the red, green, and blue light-emitting devices of the comparison display substrate are quite different. In this case, when the comparison display substrate displays a solid color picture other than red, green, and blue, there will be a significant color difference. In contrast, for the three curves Q1-G, Q2-B and Q3-R of the display substrate 100, along the direction from the front viewing angle to the right viewing angle, as the angle increases (for example, from 0 degrees to 70 degrees), the brightness value on the curve basically remains unchanged, along the direction from the front viewing angle to the left viewing angle, as the angle increases (for example, from 0 degrees to −70 degrees), the brightness value on the curve also basically remains unchanged. This is because, after the reflective dam 104 and the diffusion structure 105 are introduced, the light from a large viewing angle is concentrated into a small viewing angle through the reflective dam 104, thereby improving the brightness of the front viewing angle, and finally, the brightness of the front viewing angle and the side viewing angle are substantially the same through the diffusion effect of the diffusion structure 105. Moreover, the three curves Q1-G, Q2-B and Q3-R have a high degree of overlap, which indicates that after the processing of the reflective dam 104 and the diffusion structure 105, the light patterns emitted by the red, green, and blue light-emitting devices of the display substrate 100 have good consistency, and the color difference between the front viewing angle and the side viewing angle is very small.

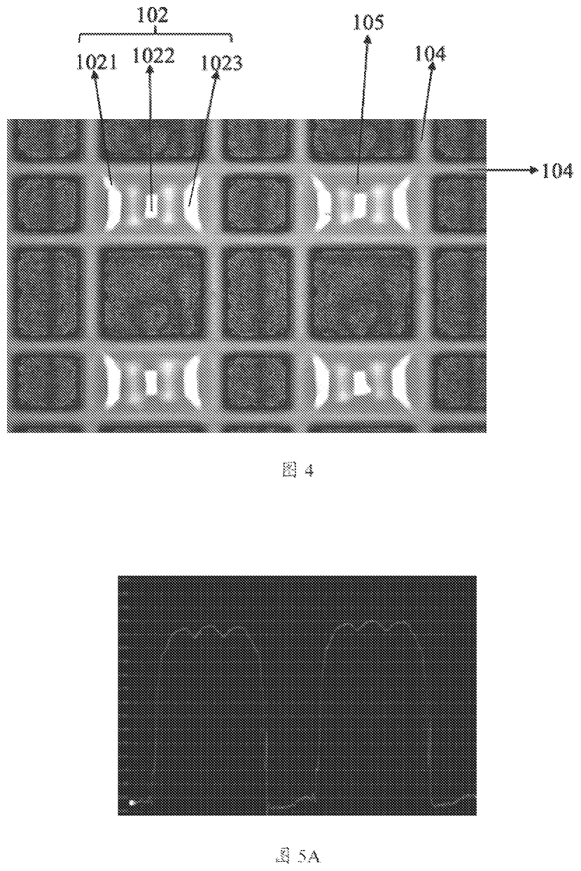

During the preparation process of the display substrate 100, the light-emitting device group 102 is first formed on the base substrate 101, the reflective dam 104 is then formed on the base substrate 101, then the diffusion structure 105 is formed on the base substrate 101, and finally the light-shielding layer 103 is formed. FIG. 4 illustrates a 3D morphology diagram under a microscope in a condition that the light-emitting device group 102, the reflective dam 104, and the diffusion structure 105 are formed on the base substrate 101 but the light-shielding layer 103 has not been formed. As illustrated in FIG. 4, the light-emitting devices 1021˜1023 are surrounded by the reflective dam 104 which is arranged horizontally and vertically. The diffusion structure 105 is formed in the groove defined by the reflective dam 104 by printing diffusion glue. The diffusion structure 105 is formed by solidifying liquid diffusion glue at high temperature. After solidification at high temperature, the diffusion glue will shrink, so the surface of the diffusion structure 105 has an uneven morphology.

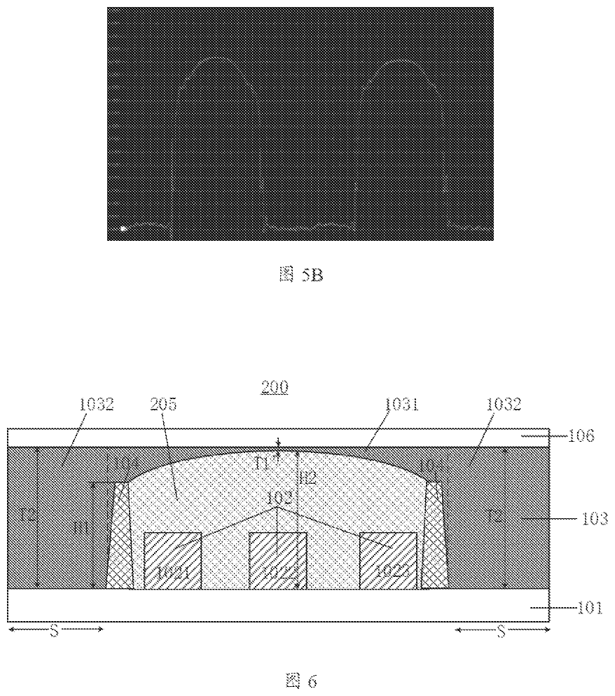

FIG. 5A illustrates a morphology graph of the diffusion structure 105 taken along the cross section of FIG. 4, where the abscissa represents the position of the display substrate along the lateral direction, and the ordinate represents the thickness. The cross section is parallel to the plane where the base substrate 101 is located, and the cross section passes through the part of the diffusion structure 105 which is located on the side of the plurality of light-emitting devices 1021˜1023 away from the base substrate 101. Optionally, the cross section may also pass through the part of the reflective dam 104 which is located on the side of the plurality of light-emitting devices 1021˜1023 away from the base substrate 101. Referring to FIG. 2, the part of the diffusion structure 105 which is located on the side of the plurality of light-emitting devices 1021˜1023 away from the base substrate 101 may be referred to as the first part 1051 of the diffusion structure 105, and the part of the reflective dam 104 which is located on the side of the plurality of light-emitting devices 1021˜1023 away from the base substrate 101 may be referred to as the first part 1041 of the reflective dam 104. The cross section of the first part 1051 of the diffusion structure 105 comprises a plurality of protrusion units, and any one of the plurality of protrusion units corresponds to one of the plurality of light-emitting device groups 102. The curve of FIG. 5A illustrates two protrusions units. As illustrated in FIG. 5A, due to the presence of the light-emitting devices 1021, 1022 and 1023, after the diffusion glue is cured, the shrinkage of the diffusion glue at the position which corresponds to the light-emitting devices is different from the shrinkage of the diffusion glue at the position which does not correspond to the light-emitting devices. At the position corresponding to the light-emitting devices, each protrusion unit of the cross section of the first part 1051 of the diffusion structure 105 comprises three protrusions, and the orthographic projections of the three protrusions on the base substrate 101 at least partially overlap with the orthographic projections of the three light-emitting devices 1021˜1023 of a corresponding light-emitting device group 102 on the base substrate 101. That is, any one of the three protrusions corresponds to one of the three light-emitting devices 1021˜1023. As illustrated in FIG. 5A, the recess between two adjacent protrusions of the three protrusions corresponds to the gap between two adjacent light-emitting devices of the three light-emitting devices 1021˜1023.

FIG. 5B illustrates a morphology graph of the diffusion structure 105 taken along the longitudinal section of FIG. 4, in which the abscissa represents the position of the display substrate along the longitudinal direction, and the ordinate represents the thickness. The longitudinal section is perpendicular to the plane where the base substrate 101 is located, and the longitudinal section avoids the position where the light-emitting device group 102 is located. As illustrated in FIG. 5B, since there is no light-emitting device in the longitudinal section, the overall curve is relatively smooth, indicating that the diffusion glue has a relatively smooth morphology after curing.

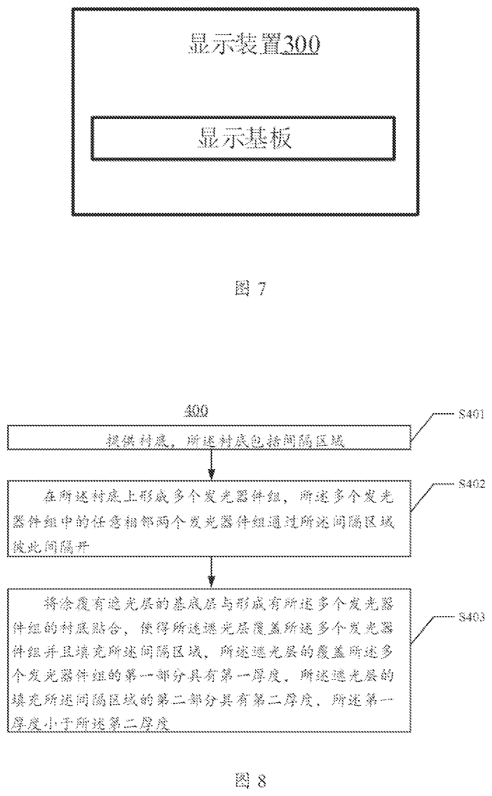

FIG. 6 illustrates a schematic cross sectional view of a partial structure of a display substrate 200. The structure of the display substrate 200 is substantially the same as that of the display substrate 100 except for the diffusion structure 205 and the first thickness T1′ of the first portion 1031 of the light-shielding layer 103. Therefore, the detailed functions of components in FIG. 6 with the same reference numbers as those in FIG. 2 can be referred to the description of FIG. 2 and will not be described again here. For the sake of simplicity, only the differences between the display substrate 200 and the display substrate 100 are introduced below.

In the display substrate 100, as illustrated in FIG. 2, the thickness H2 of the diffusion structure 105 is substantially equal to the thickness H1 of the reflective dam 104. Different from the display substrate 100, in the display substrate 200, as illustrated in FIG. 6, the distance H2 from at least one point on the surface of the diffusion structure 205 away from the base substrate 101 to the base substrate 101 is greater than the thickness H1 of the reflective dam 104. On the one hand, by increasing the thickness of the diffusion structure 205, the amount of diffusion glue and the number of diffusion particles in the diffusion structure 205 can be increased, which is beneficial to improving the diffusion effect of the diffusion structure 205 on the light emitted by the light-emitting device; on the other hand, since the diffusion structure 205 is located between the first portion 1031 of the light-shielding layer 103 and the light-emitting device group 102, by increasing the thickness of the diffusion structure 205, the first thickness T1′ of the first portion 1031 of the light-shielding layer 103 can be further reduced, thus helping further improve the transmittance of light.

In some embodiments, the surface of the diffusion structure 205 away from the base substrate 101 is a convex surface. By designing the surface of the diffusion structure 205 away from the base substrate 101 to be a convex surface, the diffusion structure 205 can have a converging effect, thereby further improving the brightness of the display substrate 200 at a front viewing angle. The radius of curvature of the surface of the diffusion structure 205 away from the base substrate 101 may be appropriately changed. The closer the shape of the diffusion structure 205 is to the hemispherical shape, the stronger the light converging effect of the diffusion structure 205 is. In some examples, the diffusion structure 205 has a hemispherical shape to form a convex lens structure, thereby converging light from the large viewing angle to the front viewing angle and improving the brightness at the front viewing angle. Compared with the comparison display substrate, under the effect of the encapsulation structure (the reflective dam 104+the diffusion structure 205+the light-shielding layer 103), the light transmittance of the display substrate 200 is further improved.

It should be noted that, similar to the display substrate 100, the cross section of the first part of the diffusion structure 205 of the display substrate 200 on the side away from the light-emitting device also comprises a plurality of protrusion units. Each protrusion unit comprises three protrusions, and the orthographic projections of the three protrusions on the base substrate 101 at least partially overlap with the orthographic projections of the three light-emitting devices 1021˜1023 of a corresponding light-emitting device group 102 on the base substrate 101. Since the amount of diffusion glue of the diffusion structure 205 is greater than the amount of diffusion glue of the diffusion structure 105, the undulation difference between the protrusion and the recess in the cross section of the first part of the diffusion structure 205 is smaller than the undulation difference between the protrusion and the recess in the cross section of the diffusion structure 105.

For other technical effects of the display substrate 200, reference may be made to the technical effects of the display substrate 100. For the sake of simplicity, other technical effects of the display substrate 200 will not be described again here.

FIG. 7 illustrates a block diagram of a display device 300, which may comprise the display substrate described in any of the previous embodiments, such as the display substrate 100 or 200. The display device 300 may be any appropriate display device, comprising but not limited to a mobile phone, a tablet computer, a television, a monitor, a notebook computer, a digital photo frame, a navigator, an e-book, and any other products or components with the display function. In an embodiment, the display screen of the display device 300 may be a splicing screen, and the splicing screen is spliced by the plurality of display substrates as mentioned above.

For the technical effects of the display device 300, reference may be made to the technical effects of the display substrate 100 or 200. For the sake of simplicity, details will not be described here.

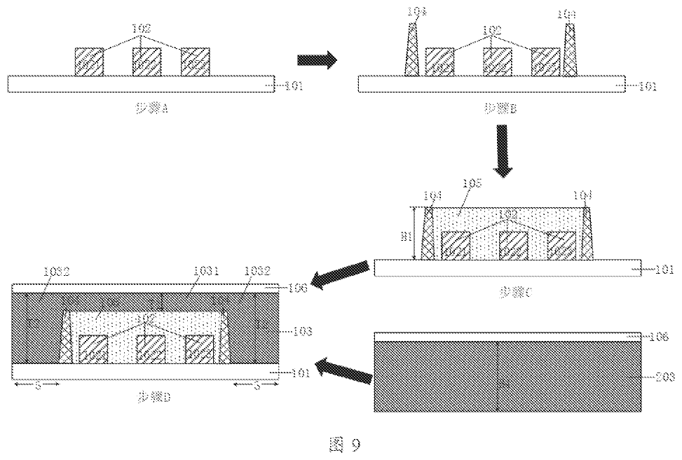

FIG. 8 illustrates a flow chart of a method 400 for preparing a display substrate. The method 400 is applicable to the display substrate described in any of the previous embodiments. Method 400 comprises the following steps.

S401: providing a base substrate 101, which comprises a spacing region S.

S402: forming a plurality of light-emitting device groups 102 on the base substrate 101, any two adjacent light-emitting device groups 102 of the plurality of light-emitting device groups 102 being spaced apart from each other by the spacing region S.

S403: assembling a base layer 106 coated with a light-shielding layer 103 with the base substrate 101 on which the plurality of light-emitting device groups 102 are formed to enable the light-shielding layer 103 to cover the plurality of light-emitting device groups 102 and to fill the spacing region S, a first portion 1031 of the light-shielding layer 103 covering the plurality of light-emitting device groups 102 having a first thickness T1, a second portion 1032 of the light-shielding layer 103 filling the spacing region S having a second thickness T2, and the first thickness T1 being less than the second thickness T2.

The light-shielding layer 103 can reduce the reflectivity of some metal traces on the display substrate to light, and can also shield the metal traces, uneven locations, and components that are not intended to be seen by the user on the display substrate, thereby making the display substrate appear to have good uniformity. By making the second portion 1032 of the light-shielding layer 103 filling the spacing region S have a thicker second thickness T2, it can well blacken the display substrate, so that the display substrate has a low black state L value. By making the first portion 1031 of the light-shielding layer 103 covering the plurality of light-emitting device groups 102 have a thinner first thickness T1, the light emitted by the light-emitting device groups 102 may not be substantially blocked, so that the light can pass through the first portion 1031 to be exited, thereby achieving high transmittance. It can be seen that by making the light-shielding layer 103 have an uneven thickness, that is, a thicker thickness T2 is provided at the position where the light-shielding layer 103 should provide a light-shielding effect so as to achieve good light-shielding, a thinner thickness T1 is provided at the position where light should be transmitted so as to achieve high transmittance, this solution can achieve high transmittance while ensuring that the display substrate has a high blackness. The realization of high transmittance can prevent the light-emitting device group 102 from additionally increasing the brightness, thereby reducing the power consumption of the display substrate.

FIG. 9 illustrates a schematic structural diagram of the display substrate at different stages of preparation. The method of preparing a display substrate is described in more detail below with reference to FIG. 9.

In step A, a base substrate 101 is first provided. Then, a plurality of light-emitting device groups 102 are formed on the base substrate 101, and any two adjacent light-emitting device groups 102 are spaced apart from each other by the spacing region S. Each light-emitting device group 102 comprises a plurality of light-emitting devices. For example, each light-emitting device group 102 comprises three light-emitting devices 1021, 1022 and 1023. The three light-emitting devices 1021, 1022 and 1023 may respectively emit light of different colors. For example, the light-emitting device 1021 may emit red light, the light-emitting device 1022 may emit green light, and the light-emitting device 1023 may emit blue light. In some embodiments, each light-emitting device may be a Mini light-emitting diode (Mini LED) or a Mirco light-emitting diode (Mirco LED). The plurality of light-emitting devices may be formed on the base substrate 101 by printing.

Then, in step B, a reflective dam 104 is formed on the base substrate 101 on which the light-emitting device groups 102 are formed. For example, the gray reflective dam 104 can be formed by printing. The reflective dam 104 is arranged along the first direction DI and the second direction D2 intersecting with the first direction D1, and the reflective dam 104 at least surrounds each light-emitting device group 102. The first direction D1 may be, for example, a horizontal direction, and the second direction D2 may be, for example, a vertical direction perpendicular to the horizontal direction. In some embodiments, the reflective dam 104 may require multiple printings depending on its thickness. In an example, the thickness of the reflective dam 104 is 150 μm, while the thickness of the reflective dam material printed each time is about 50 μm, therefore, it is necessary to print three times in a stack manner to form the reflective dam 104 with the required thickness. The reflective dam 104 that has just been printed is viscous. Due to gravity, the top and bottom of the reflective dam 104 have a slope, that is to say, the longitudinal section of the reflective dam 104 is trapezoidal, and the longitudinal section is the section of the reflective dam 104 along the thickness direction of the base substrate 101. In some embodiments, the angle between the slope of the trapezoid and the bottom is about 10°˜30°, and the angle may be adjusted by adjusting the viscosity of the reflective dam material.

Then, in step C, the diffusion structure 105 is filled in the filling region defined by the reflective dam 104, so that the diffusion structure 105 covers each light-emitting device group 102, and the orthographic projection of each light-emitting device group 102 on the base substrate 101 falls within the orthographic projection of the diffusion structure 105 on the base substrate 101. The diffusion structure 105 comprises diffusion glue and diffusion particles distributed in the diffusion glue. In some examples, the diffusion glue may be transparent OCA glue, and the diffusion particles may be nanoscale TiO₂ particles or SiO₂ particles or other nanometer-sized particles with diffusion effects. The diffusion structure 105 can adjust the light pattern emitted by the light-emitting device and improve the phenomenon of color cast. The diffusion structure 105 separates the first portion 1031 of the light-shielding layer 103 from the plurality of light-emitting device groups 102, so that direct contact between the light-shielding layer 103 and the light-emitting device groups 102 can be avoided.

Finally, in step D, the base layer 106 coated with the light-shielding glue 203 is assembled with the base substrate 101 on which the plurality of light-emitting device groups 102, the reflective dam 104 and the diffusion structure 105 are formed. The light-shielding glue 203 may be pre-coated on the base layer 106 before preparing the display substrate, or may be coated on the base layer 106 during any stage of preparation of the display substrate. The step D may specifically comprise the following operations: aligning the base layer 106 coated with the light-shielding glue 203 with a uniform thickness with the base substrate 101 on which the plurality of light-emitting device groups 102, the reflective dams 104 and the diffusion structures 105 are formed; then, deforming the light-shielding glue 203 by vacuum lamination and extrusion, to make a part of the light-shielding glue 203 extrude from a position aligned with the light-emitting device group 102 to a position aligned with the spacing region S, so as to form the light-shielding layer 103 comprising the first portion 1031 with the first thickness T1 and the second portion 1032 with the second thickness T2; and performing assembling to form a display substrate.

That is to say, during the preparation process, the light-emitting device group 102 is first formed on the base substrate 101 (which may be also referred to as die-bonding), then the reflective dam 104 is formed, then the diffusion structure 105 is formed, and finally, the base layer 106 coated with the light-shielding glue 203 is assembled to the base substrate 101 formed with the plurality of light-emitting device groups 102, the reflective dam 104 and the diffusion structures 105 to form a display substrate. Since the thickness H1 of the reflective dam 104 is relatively large, if the reflective dam 104 is formed before the die-bonding, the reflective dam 104 will affect the subsequent die-bonding process.

As illustrated in FIG. 9, in the thickness direction of the base substrate 101, the thickness H4 of the light-shielding glue 203 is smaller than the thickness H1 of the reflective dam 104, after the light-shielding glue 203 is compressed and deformed, the thickness of the light-shielding glue 203 above the light-emitting device becomes thinner, thereby increasing the transmittance of light. In some embodiments, the thickness H4 of the light-shielding glue 203 is 20˜60 μm smaller than the thickness H1 of the reflective dam 104. By making the light-shielding layer 103 above the light-emitting device group 102 have a thin thickness T1, a higher transmittance can be achieved. By filling the spacing region S where there is no diffusion structure 105 with the light-shielding layer 103, the light-shielding layer 103 at the spacing region S has a thick thickness T2, the blackening effect on the display substrate can be achieved. Therefore, this solution can achieve high transmittance encapsulation while ensuring a high blackness of the display substrate.

It will be understood that although the terms first, second, third, etc. may be used herein to describe various elements, components, regions, layers and/or portions, these elements, components, regions, layers and/or portions should not be limited by these terms. These terms are only used to distinguish an element, component, region, layer or portion from another element, component, region, layer or portion. Thus, a first element, component, region, layer or portion discussed above could be termed a second element, component, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, components and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing. Thus, the regions illustrated in the figures are schematic in nature and their shapes are not intended to illustrate the actual shape of a region of a device and are not intended to limit the scope of the present disclosure.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A display substrate comprising:
a base substrate comprising a spacing region;
a plurality of light-emitting device groups on the base substrate, any two adjacent light-emitting device groups of the plurality of light-emitting device groups being spaced apart from each other by the spacing region; and
a light-shielding layer on the base substrate,
wherein the light-shielding layer covers the plurality of light-emitting device groups and fills the spacing region, a first portion of the light-shielding layer covering the plurality of light-emitting device groups has a first thickness, a second portion of the light-shielding layer filling the spacing region has a second thickness, and the first thickness is less than the second thickness.

2. The display substrate according to claim 1, wherein the first portion of the light-shielding layer is spaced apart from the plurality of light-emitting device groups in a thickness direction of the base substrate.

3. The display substrate according to claim 1, further comprising a reflective dam, wherein the reflective dam is arranged on the base substrate along a first direction and a second direction intersecting with the first direction, and the reflective dam at least surrounds each of the plurality of light-emitting device groups.

4. The display substrate according to claim 3, wherein each light-emitting device group comprises a plurality of light-emitting devices, and a thickness of the reflective dam is greater than a thickness of a light-emitting device in a thickness direction of the base substrate.

5. The display substrate according to claim 3, wherein the reflective dam surrounding each light-emitting device group forms a reflective cup.

6. The display substrate according to claim 3, further comprising a diffusion structure,
wherein the diffusion structure comprises a diffusion glue and diffusion particles distributed in the diffusion glue, and
wherein the diffusion structure covers each light-emitting device group, and an orthographic projection of each light-emitting device group on the base substrate falls within an orthographic projection of the diffusion structure on the base substrate.

7. The display substrate according to claim 6, wherein in a thickness direction of the base substrate, the first portion of the light-shielding layer is spaced apart from the plurality of light-emitting device groups by the diffusion structure.

8. The display substrate according to claim 7, wherein each light-emitting device group comprises a plurality of light-emitting devices, and the diffusion structure is at least on a side of the plurality of light-emitting devices away from the base substrate and in a region between any two adjacent light-emitting devices of the plurality of light-emitting devices.

9. The display substrate according to claim 8, wherein
a part of the diffusion structure on the side of the plurality of light-emitting devices away from the base substrate is a first part of the diffusion structure, a cross section of the first part of the diffusion structure comprises a plurality of protrusion units, any one of the plurality of protrusion units corresponds to one of the plurality of light-emitting device groups, the cross section of the first part of the diffusion structure is a section of the first part of the diffusion structure in a direction parallel to the base substrate, and
each light-emitting device group comprises three light-emitting devices, each protrusion unit comprises three protrusions, and orthographic projections of the three protrusions on the base substrate at least partially overlap with orthographic projections of the three light-emitting devices of a corresponding light-emitting device group on the base substrate.

10. The display substrate according to claim 8, wherein a thickness of the diffusion structure is greater than a thickness of a light-emitting device in the thickness direction of the base substrate.

11. The display substrate according to claim 8, wherein the diffusion structure is further on a surface of the reflective dam away from the base substrate.

12. (canceled)

13. The display substrate according to claim 6, wherein an orthographic projection of the first portion of the light-shielding layer on the base substrate at least partially overlaps with the orthographic projection of the diffusion structure on the base substrate, and an orthographic projection of the second portion of the light-shielding layer on the base substrate does not overlap with the orthographic projection of the diffusion structure on the base substrate.

14. The display substrate according to claim 6,
wherein in a thickness direction of the base substrate, a thickness of the diffusion structure is substantially equal to a thickness of the reflective dam; or
wherein a distance from at least one point on a surface of the diffusion structure away from the base substrate to the base substrate is greater than a distance from a surface of the reflective dam away from the base substrate to the base substrate.

15. (canceled)

16. The display substrate according to claim 14,
wherein the distance from at least one point on the surface of the diffusion structure away from the base substrate to the base substrate is greater than the distance from the surface of the reflective dam away from the base substrate to the base substrate, and
wherein the surface of the diffusion structure away from the base substrate is a convex surface, and a shape of the diffusion structure is hemispherical.

17. (canceled)

18. The display substrate according to claim 6, further comprising:
a plurality of driving circuits; and
a base layer on a side of the light-shielding layer away from the base substrate,
wherein any one of the plurality of driving circuits is electrically connected to one of the plurality of light-emitting device groups, and the reflective dam and the diffusion structure together wrap each light-emitting device group and each driving circuit, and
wherein the light-shielding layer is attached to a surface of the base layer facing the base substrate.

19. (canceled)

20. (canceled)

21. The display substrate according to claim 1, wherein the light-shielding layer comprises a flame retardant.

22. A display device comprising the display substrate according to claim 1.

23. A method of preparing a display substrate comprising:
providing a base substrate, the base substrate comprising a spacing region;
forming a plurality of light-emitting device groups on the base substrate, any two adjacent light-emitting device groups of the plurality of light-emitting device groups being spaced apart from each other by the spacing region; and
assembling a base layer coated with a light-shielding layer with the base substrate on which the plurality of light-emitting device groups are formed to enable the light-shielding layer to cover the plurality of light-emitting device groups and to fill the spacing region, a first portion of the light-shielding layer covering the plurality of light-emitting device groups having a first thickness, a second portion of the light-shielding layer filling the spacing region having a second thickness, and the first thickness being less than the second thickness.

24. The method according to claim 23, before the assembling a base layer coated with a light-shielding layer with the base substrate on which the plurality of light-emitting device groups are formed, further comprising:
forming a reflective dam on the base substrate, the reflective dam being arranged along a first direction and a second direction intersecting with the first direction, and the reflective dam at least surrounding each of the plurality of light-emitting device groups; and
filling a diffusion structure in a region defined by the reflective dam to enable the diffusion structure to cover each light-emitting device group, an orthographic projection of each light-emitting device group on the base substrate falling within an orthographic projection of the diffusion structure on the base substrate,
wherein the assembling a base layer coated with a light-shielding layer with the base substrate on which the plurality of light-emitting device groups are formed, comprises;
aligning the base layer coated with a light-shielding glue having a uniform thickness with the base substrate on which the plurality of light-emitting device groups, the reflective dam and the diffusion structure are formed, a portion of the light-shielding glue being extruded from a position aligned with the light-emitting device groups to a position aligned with the spacing region through vacuum lamination and extrusion, to form the light-shielding layer comprising the first portion having the first thickness and the second portion having the second thickness, the light-shielding layer being attached to the base substrate.

25. (canceled)

26. (canceled)

27. The method according to claim 24,
wherein the forming a reflective dam on the base substrate, comprises: forming the reflective dam on the base substrate through a method of multiple printings in a stacked manner,
wherein a longitudinal section of the reflective dam is a trapezoid, and the longitudinal section of the reflective dam is a section of the reflective dam in a thickness direction of the base substrate, and
wherein forming the plurality of light-emitting device groups on the base substrate is before forming the reflective dam on the base substrate.

28. (canceled)
